(19) United States
(12) Patent Application Publication
(10) Pub. No.: US 2023/0314090 A1
(43) Pub. Date: Oct. 5, 2023

(54) Multi-level hierarchical hybrid structures to replace single-level wicks in next generation vapor chambers

(71) Applicant: The Board of Trustees of the Leland Stanford Junior University, Stanford, CA (US)

(72) Inventors: Sougata Hazra, Stanford, CA (US); Mehdi Asheghi, Oakland, CA (US); Kenneth E. Goodson, Portola Valley, CA (US); Chi Zhang, Palo Alto, CA (US)

(21) Appl. No.: 18/129,657

(22) Filed: Mar. 31, 2023

Related U.S. Application Data
(60) Provisional application No. 63/326,109, filed on Mar. 31, 2022.

(51) Int. Cl. F28D 15/04; F28F 3/02

(52) U.S. Cl. CPC F28D 15/046; F28F 3/022; F28D 2015/0225

(57) ABSTRACT

Improved vapor chambers are provided using monolithic wick structures having deep features (≥150 um) and two or more different feature heights above the substrate. Such monolithic multi-level wick structures provide improved performance in vapor chambers by alleviating the tradeoff between fluid transport (which favors tall pin-fins) and heat transfer (which favors short pin-fins).

### CROSS REFERENCE TO RELATED APPLICATIONS

This application claims priority from U.S. Provisional Patent Application 63/326,109 filed Mar. 31, 2022, which is incorporated herein by reference.

### GOVERNMENT SPONSORSHIP

None.

### FIELD OF THE INVENTION

### Background

The recent demands for faster and better performing electronics coupled with superior integrated circuit fabrication capability (transistor size ˜5 nm) have enabled significantly increased transistor density per chip(let)—recent research is trying to pack such chiplets extremely close to each other, possibly even exploiting vertically integrable architecture in order to keep increasing output power density and thus keep Moore's Law alive. But along with high output power, these chips (typically, each of these produce heat flux ˜300 W/cm², this is expected to go up to more than 500 W/cm² in the next decade) also show an exponential increase in waste heat generation, which if not dissipated effectively can compromise device efficiency and performance capability. In extreme cases, it might lead to an uncontrolled rise in chip temperature ultimately leading to burnt chips and device failure.

In fact, the waste heat dissipation from packing such power dense chips closely together is so prohibitively large that it has become the primary bottleneck preventing researchers and industry from increasing the maximum power density achievable today. To overcome this barrier, thermal researchers have come up with heat spreaders. Most conventional heat spreaders used in today's electronic devices are called Vapor Chambers (VC) and they have two pieces: a) The evaporator—This is the main heat transfer layer, and sits directly above the heat producing chips (hot-spots). A microstructured wick is used in the evaporator to act as the site for liquid to evaporate, thus extracting heat from the chips. The produced vapor spreads within the VC and comes in contact with the relatively colder b) Condenser—The condenser is responsible for giving the expanding vapor a site to accumulate and condense before flowing back to the evaporator. The most important determinant of device efficiency is the microstructured wick in the evaporator—this is responsible for governing the two-phase heat transfer over the hot-spots, and also determines how effectively fluid is routed back from the condenser to the evaporator side. Usually, there are two-competing effects that determine the efficacy of an evaporator microstructure. A smaller microstructure pore size (smaller height in micro-pillar wicks) leads to better thermal performance of the VC—it helps the microstructure retain fluid better, reduces the thin film conduction resistance of the fluid which fills the microstructure (as seen in previous studies), and increases the overall area surface available for evaporative heat transfer. But simultaneously, a smaller microstructure pore size is also associated with low fluid permeability (or high viscous flow resistance), thus such wicks are unable to reroute fluid in high quantities from the condenser back to the evaporator. This puts a mass transport limited upper bound on the maximum heat flux that can be dissipated using the VC.

To mitigate the effects of these two competing phenomena, research has been directed towards creating 3D hybrid wicks with a clever combination of both small pore sized nano-microscopic features and larger pore sized micro-macroscopic features, hoping to utilize the functionality of both these structures in conjunction to create high performing vapor chambers. The idea is to use the larger microscopic backbone to wick large quantities of fluid to the hot-spots without difficulty (thus overcoming the capillary limit) while the smaller nano-microscopic features will provide the necessary small pore size to maintain superior thermal performance.

A promising VC design that can utilize the best of both worlds can be made by combination of taller pin fins (these could also be channels, mesh structures, arteries etc.) and smaller pin-fins—The taller pin-fins when placed away from the hotspots will act as effective liquid rerouting pins and the smaller ones will be placed on the hot-spots to maintain superior thermal performance.

Additionally, the taller pins could also serve as integration sites (e.g. for bonding with condensers) for structural integrity and reliability of large area devices.

However, making such hierarchical, heterogeneous wicks, using conventional cleanroom-based techniques is extremely difficult. Conventional cleanroom techniques can create structures that we call 2.5D (the lithography design can be etched or extruded to the same height value everywhere on the wafer, but different parts of the lithography design cannot have different depths into the wafer). Thus, research into hybrid wicks so far have only been limited to pseudo-hierarchical structures by introducing nanoscopic roughness features (by sintering Cu powder, CuO nanostructuring, CNT growth, hydrothermal NW synthesis and in rare cases laser rastering) all over a monoporous (2.5D) structure (grooves, channels, pin-fins, arteries) made using conventional lithography. These structures can be called “pseudo-hierarchical” instead of fully hierarchical since these structures are just roughened versions of their original 2.5D backbones that were made using conventional lithography.

It is difficult or impossible to fabricate fully 3D wick structures using wafer bonding of 2D wick structures because the wick features at intermediate layers would typically be disconnected from each other, making wafer bonding to achieve a 3D structure impossible. Avoiding this problem by connecting the wick features to each other in each intermediate layer would result in significant undesirable compromises in the fluidic design. As the following discussion shows, it is also impossible to make 3D wick structures with conventional lithography.

In conventional lithography-based cleanroom process flows, creation of etched features usually follows these steps:
a) Coating Photoresist (PR) on the wafer—When PR is puddle dispensed at the center of a Silicon wafer spinning at a high RPM, it spreads radially outward to create a thin (1 um to 10 um depending on PR viscosity and spin RPM), uniform and conformal coating over the wafer. Thicker PR (7 to 10 um) is not desirable as it increases the minimum resolution that can be achieved after exposure of a design in step b. The uniformity of the PR layer is also highly crucial for success of the downstream processes.
b) Exposure of design to pattern the PR and development of exposed features—Next, UV light of appropriate wavelength, energy and distance is used to expose the design layer on the PR (this selectively changes the chemical composition of the PR and makes it soluble in the developer solvent) and a developer is used (in most cases, MF26A-2% TMAH soln.) to wash away the exposed areas (if the PR is positive). Non-uniform coating of PR leads to unsatisfactory exposure, causing overexposure in certain parts of the wafer and underexposure in others. Thus, in a way, the success of the overall process rests entirely upon step (a) and our ability to achieve a thin, conformal coat of PR on the wafer.
c) Deep Silicon Etch—Finally, the wafer is etched in a deep Silicon etcher that uses time-multiplexed Bosch process to anisotropically etch features in the Silicon selectively where the exposure had happened in the previous step (the PR which is left behind acts as a masking layer and prevents etching in these zones). After this process, the features created across the wafer have the same height/depth.

To achieve multi-depth structures using this technique, where different parts of the wafer need to have different etch depths, the sequence of steps (a, b and c) needs to be repeated multiple times with a different exposure design in step b, and different etch time in step c.

The primary challenge arises in step (a) itself when PR is attempted to be spun on the wafer with features already etched in them. The spinning process is satisfactory (thin and uniform) when the PR thickness (ideally, less than 4 um for low exposure resolution of 2 um in step b) is much larger compared to the etch height of the features. Thus, in cases (some cases of IC fabrication) where the already etched feature height is <=1 um, this process works perfectly, but in most useful applications of microfluidics, liquid cooling, optics and semiconductor fabrication, these etch depths can range anywhere from 1 um to 500-600 um, and leads to unsatisfactory coating in step a. Several problems like streaking (PR layer being wrinkled after hitting an etched feature), fingering (PR getting trapped in a deep cavity/channel and progressing along those channels only), and incomplete coverage (PR hitting the corner of an etched feature and failing to cover the rest of the wafer) mar the spin coating process in step a—thereby leading to failure of the whole process.

Accordingly, it would be an advance in the art to provide monolithically fabricated multilevel 3D wick structures.

### SUMMARY

Here we consider application of an unconventional process flow using commonly used cleanroom tools which mitigates all these problems and enables us to create multi-level hierarchical wick structures with ease. In one example, we have replaced the etch mask layer from PR with Silicon Oxide (SiO). The idea is to perform multiple rounds of lithography to pattern this new SiO mask layer instead of patterning the Silicon directly, after which, through deep Si etching this pattern gets scaled and transferred to the Silicon. In one example of this new process flow the steps are as follows:
i) Deposit Silicon Oxide on the wafer—CVD (Chemical Vapor Deposition) or HDPECVD (High Density Plasma Enhanced CVD) process is used to deposit a 1-2 um layer of Silicon Oxide (SiO) on a bare Silicon wafer (Thermal oxide also works fine). This acts as a hard mask during the Deep Silicon Etching.
ii) Coating PR (same as step a),
iii) Exposure and Development (same as step b),
iv) Etch SiO—Silicon Oxide is etched precisely to achieve the desired step height. It should be noted that the maximum step height in SiO thus, cannot exceed the total initial SiO thickness (1-2 um).

Multiple rounds of step (ii, iii and iv) (lithography+SiO etch) are performed on the wafer to create a hierarchical multi-level structure in the SiO layer itself. In this situation, the most crucial step (step a or step ii) of spinning the PR on the SiO coated wafer works perfectly. The obtained PR layer is thin and uniform since the PR thickness (4 um) is >4× larger than the etched step height in SiO (˜1 um).

The final step is performing a Deep Silicon etch using the 3D hierarchical SiO layer as the hard-mask. After the etching has been completed and all the SiO has been consumed, the 3D structure that was created in the SiO (by multiple rounds of lithography) is scaled by the etch selectivity (ratio of etch rate of Si to etch rate of the mask layer, SiO) and transferred to the Si. Additionally, SiO is much superior to hardened PR as an etch stop mask layer providing Si:SiO selectivity of 200-300 during deep Si etch using the Bosch process (for comparison, same etching recipe provides Si:PR selectivity of 80-150), which enables us to create structures as tall as 400-500 um.

Preliminary tests have demonstrated the ability to create 3D hierarchical features of nominal dimensions (width)˜5-10 um with aspect ratios (height/width) as large as 10-15. The resolution can be further improved by using e-beam lithography instead of conventional lithography.

This process flow of creating multi-level structures has been tested more than 5 times with different orders of step heights (250 nm through 900 nm) to establish reliability and repeatability of the process. Moreover, this process employs only a single step of deep Si etch, thus making it much less expensive and time consuming as compared to the conventional lithography route which employs multiple rounds of deep Si etch (number of levels required in the structure=number of deep Si etch steps). This will increase throughput while simultaneously reducing cost per device when used in an industrial mass production scenario. This approach could open a much wider window of opportunity for design, optimization and fabrication of 3D silicon-based micro/nanostructures that have not been previously seen or explored.

Further details on this method are provided in U.S. patent application Ser. No. 18/084,303, filed Dec. 19, 2022 and hereby incorporated by reference in its entirety.

In the context of passive wicking-based heat spreaders (heat pipes, vapor chambers), this fabrication approach enables us to create new structures, such as multi-level pillar array type structures (more than 1 height/depth of pillars) with a capability to make microstructures with total height>150 um with resolution (defined as minimum achievable step height between two levels or heights) as low as 2-3 um.

Such multi-level pin fin array type structures have never been fabricated by anyone previously. General multi-level structures have been created before but they have been limited to have moderate aspect ratios and be less than 100 um height. Our work specifically deals with total height>150 um and feature lateral width as small as allowed by lithography (>=1 um).

Such multi-level structures provide significant advantages.
Good Heat Spreaders have —
   i) High capillary performance of evaporator wick (more amount of liquid should wick fast from condenser back to evaporator)—Tall features wick liquid more quickly.
   ii) Low Wick thermal resistance (wicks should be thin so that liquid trapped in between has smaller thermal resistance)—Short features mean low thermal resistance.

If a single-level evaporator has only tall pins then thermal performance is poor (less amount of heat dissipated, low CHF). If they have only short pins then capillary performance is poor (fluid does not reach device center, severe limit on device size, thus technology not scalable)

We are able to make multi-level pin arrays, that will include both tall and short pins to solve the problem—tall pins, or arteries or channels will be placed to provide fluid path from reservoir to device center, short pins will be directly placed on hot-spots, they will retain fluid longer, delay dry-out (device failure) and provide improved thermal performance (specifically, low thermal resistance). Additionally there can be a few extra tall pillars—for mechanical support, sustain high pressure in large devices, provide shorter path for liquid return from condenser to evaporator.

Our demonstration of creating these hierarchical structures without deviating from standardized cleanroom techniques and processes, opens a world of possibilities in terms of the types and topology of structures that can be created in wafers (could also be extended to wafers of other materials like GaAs).

This technology is expected to have significant impact on industries that rely primarily on micro-nano structures for the efficacy of their devices. Micro-nano structures and wicks are widely used in microfluidics, liquid cooling, water purification and harvesting, sorption, desorption processes, sensors, and varieties of MEMS and NEMS technologies. Fabrication difficulties have been the primary inhibitor to both research and adoption of such hybrid, hierarchical wicks in existing technology. This novel process flow for easy creation of hybrid wick will, hopefully, encourage more detailed investigation and adoption of these structures in standard technologies and eventually drive up their respective performance metrics by several orders of magnitude.

### BRIEF DESCRIPTION OF THE DRAWINGS

FIG. 1 shows an exemplary embodiment of the invention.

FIGS. 2A-B show two views of an exemplary monolithically microfabricated array of wicking features.

FIGS. 2C-D shows examples of the use of the monolithically microfabricated array of wicking features of FIGS. 2A-B in a vapor chamber.

FIG. 3 shows examples of multi-level pins.

FIG. 4 shows examples of pins having holes and/or roughness.

FIG. 5 shows an exemplary pin array having a gradient of pin height.

### DETAILED DESCRIPTION

### A) General Principles

In this work we provide multi-level post (pillar) type structures (note that multi-level pin fin type structures have not been reported in any previous study) with the following characteristics —
1. Will have two or more levels of pillars (conventional methods can also make more than one level structures)
2. The maximum height difference in the multi-level structure is more than 150 um (conventional grayscale lithography technique has only demonstrated 3D structures with a maximum height difference of 100 um). We can easily push this to more than 150 um and this is a major advantage of our approach. This is especially useful in many applications since structures associated with microfluidics and microfluidic cooling technologies (here we can mention passive heat spreaders, like vapor chamber of heat pipe) operate in the micro-meso scale.
3. The resolution of steps achievable is also pretty high in our method, 2-3 um as compared to conventional chip stacking (chip stacking has a resolution of 30-50 um for the in-between middle layers)

We provide improvement (higher thermal performance and being able to scale up the technology) in passive cooling devices by having multi-level microstructures of different heights. The performance of most conventional passive cooling devices (vapor chambers, heat pipes) is almost solely determined by the microstructure pore size on the evaporator wick. A smaller microstructure pore size helps in fluid retention over the hot-spots, reduces conduction resistance of the thin film of fluid and enhances heat transfer area during device operation. Although, the full potential of these small pored structures are not utilized as smaller pore sizes are also accompanied by other problems. Smaller pore sizes simultaneously reduce the total amount of fluid that can be successfully wicked back from the condenser to the evaporator thus putting a transport-based limit (called, capillary limit). These issues lead to two more issues that are the primary hurdles to widespread use and commercialization—low critical heat flux (CHF) that can be dissipated from the hotspot and device cannot be scaled up to dissipate heat from larger areas. To mitigate these problems, truly 3D structures can be made monolithically out of a single wafer (e.g., a silicon wafer) as described herein.

These devices could have a combination of features—taller pin-fins, channels, arteries wherever fluid transport is desired and have smaller pored structures over and near the hot-spots to maintain low resistance and good thermal performance. The standardization of the new method (which can be done with great ease) into processing flows in industry and academia will significantly expand the design space available to us in terms of structure types and topologies we can make monolithically. Additionally, the vapor chamber can also have some much taller pin fins interspersed in the heater zone. These are structural pins acting as bonding sites with the other layer, to provide mechanical support to the overall device and sustain a higher pressure before bursting. Moreover, these pins also provide shorter pathways for liquid return from the condenser to the evaporator, thus increasing capillary transport limited CHF.

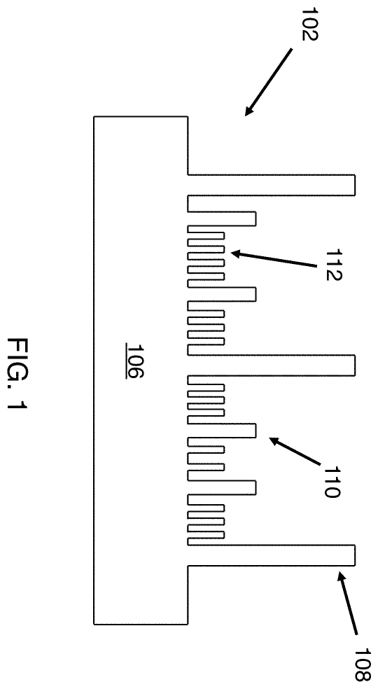

FIG. 1 shows an exemplary embodiment of the invention that is a passive wicking-based microfluidic heat spreader 102 including:
a monolithically microfabricated array of wicking features (e.g., pins 108, 110, 112), where the monolithically microfabricated array of wicking features includes a substrate 106 and features having two or more different vertical feature heights above the substrate (e.g., features 108, 110, 112 have three different heights above substrate 106). The monolithically microfabricated array of wicking features does not include any wafer-to-wafer bonds, and it includes features having a vertical feature height of 150 microns or more. As indicated above, such deeply etched wicking structures are not possible to make with conventional fabrication methods, and thus, to the best of our knowledge, have not been previously reported.

Here a monolithically microfabricated array of wicking features is an array of wicking features fabricated by processing a single wafer (as opposed to processing two or more wafers and then bonding them together). As a result, a monolithically microfabricated array of wicking features has the structural feature of not including any wafer-to-wafer bonds.

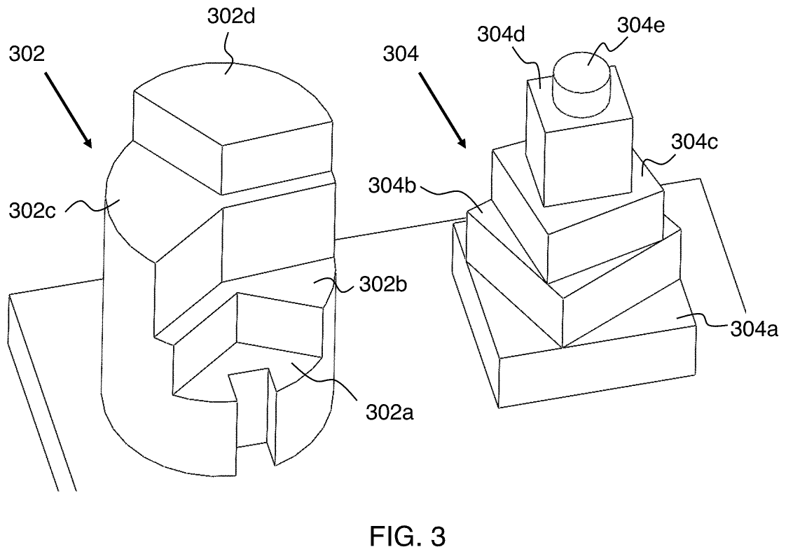

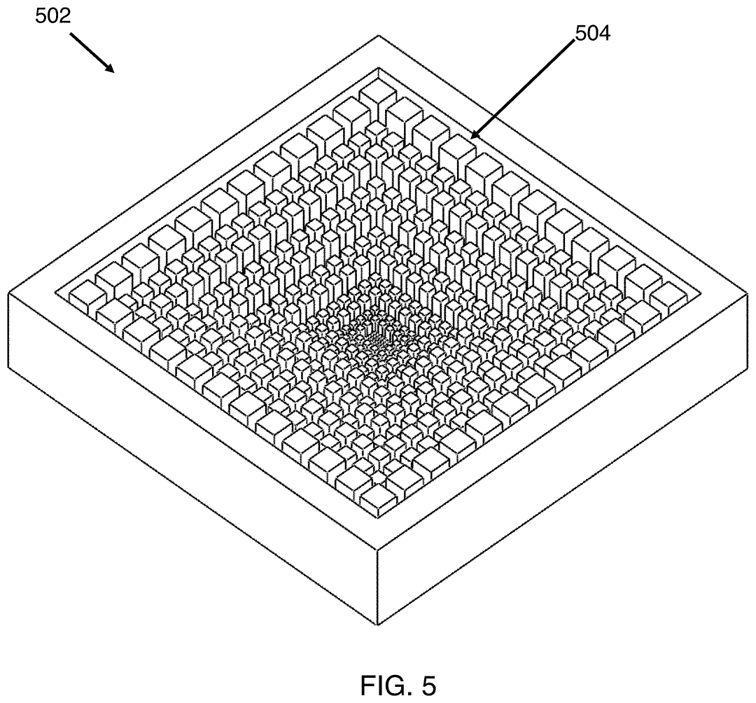

The wicking features can include one or more pins that rise vertically from the substrate surface. Vertical heights of the one or more pins can be configured to provide a vertical height gradient (FIG. 5) in the monolithically microfabricated array of wicking features. One or more of the pins can be a multilevel pin (FIG. 3) having two or more pin features with different vertical heights above the substrate surface.

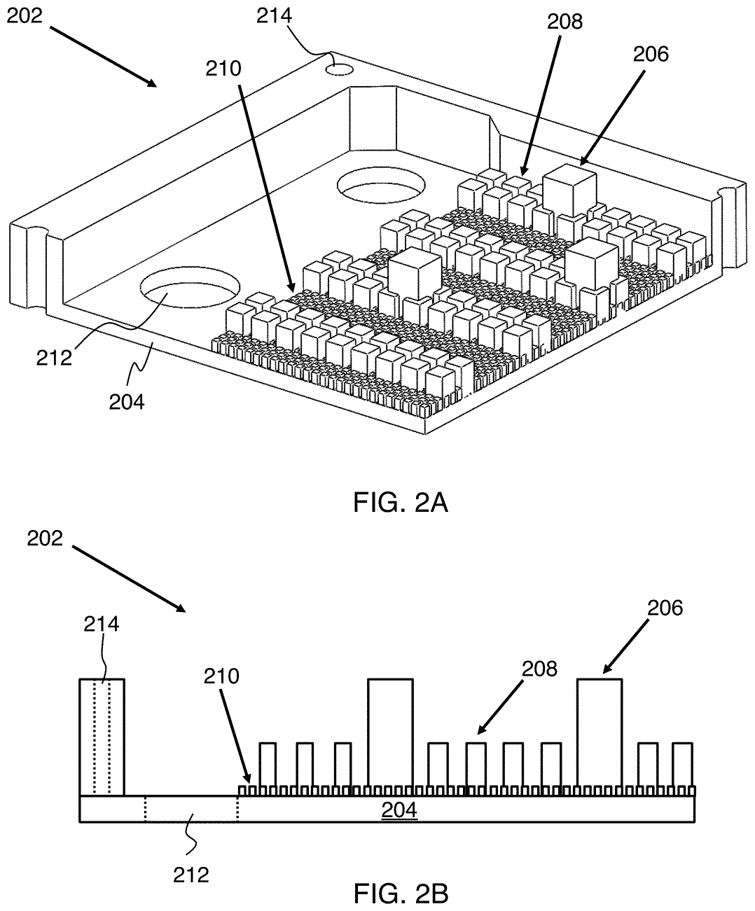

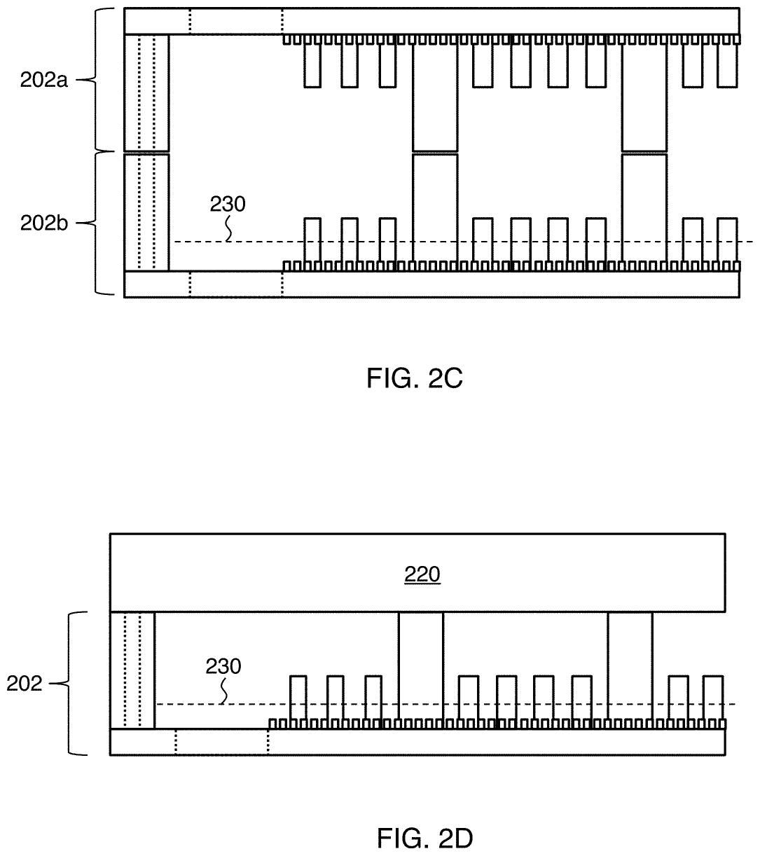

One or more fluid passages (e.g., 212 on FIG. 2A) can be present in the substrate. At least one of the fluid passages can be configured as a hole passing vertically though the substrate (e.g., 212 on FIG. 2A).

One or more vertical vias (e.g., 214 on FIG. 2A) can pass through the substrate. A height/width aspect ratio of at least one of the vertical vias can be 10 or more.

A vapor chamber can include a first passive wicking-based microfluidic heat spreader as above (e.g., 202a on FIG. 2C, and a second passive wicking-based microfluidic heat spreader as above (e.g., 202b on FIG. 2C), where the first and second passive wicking-based microfluidic heat spreaders are disposed to form an enclosure. In this example, an evaporative coolant (e.g., 230 on FIG. 2C is disposed in the enclosure.

A vapor chamber can include a passive wicking-based microfluidic heat spreader as above (e.g., 202 on FIG. 2D), a capping layer (e.g., 220 on FIG. 2D) disposed to form an enclosure with the passive wicking-based microfluidic heat spreader, and an evaporative coolant (e.g., 230 on FIG. 2D) disposed in the enclosure.

### B) Examples

FIGS. 2A-B show another exemplary embodiment. Here passive wicking-based microfluidic heat spreader 202 includes substrate 204, tall pins 206, intermediate pins 208 and short pins 210. It also includes fluid inlet/outlet ports (e.g., port 212) through the substrate and vertical via(s) (e.g., 214). As indicated above, pins of different height have different functions. Short pins 210 are disposed near hotspots for better thermal performance, intermediate pins 208 provide better fluid transport from device edge to center, and tall pins 206 can act as mechanical support pillars.

Vertical vias are often desirable for establishing multi-layer multifunctional chips. Our approach enables easy creation of high aspect ratio vertical vias, that are expected to enable next generation 3D electronic vertically expanded chiplets. Vertical vias and other through holes (for fluid charging or flow) can be simultaneously fabricated with ease during wick formation because of the one shot etching employed by this process.

The fluid ports are typically much larger in lateral dimension than the vias to accommodate flow, so their aspect ratio is lower than that of the vias. These are easy to make, a variety of other methods can be used—laser cutting, water jet cutting, micromachining, drilling. Our method enables simultaneous creation of all these different features (active wick microstructures, other steps in silicon for integration, roughness, holes, vertical vias, through ports) monolithically out of a single substrate.

As indicated above, a vapor chamber can be formed by making an enclosure that includes wick structures as described herein. FIG. 2C shows a first example, where wick structures 202a and 202b form an enclosure in which evaporative coolant 230 is disposed. Here wick structure 202b can be the condenser and wick structure 202a can be the evaporator (as shown), or vice versa. FIG. 2D shows a second example, where wick structure 202 and capping layer 220 form an enclosure in which evaporative coolant 230 is disposed. Here it is preferred that wick structure 202 be the evaporator, as shown.

Single features, e.g., a single pin, can individually be multi-level. FIG. 3 shows some examples. Here pin 302 includes features 302a, 302b, 302c, 302d at different heights. Similarly, pin 304 includes features 304a, 304b, 304c, 304d, 304e at different heights. In a passive heat spreader, these individual pin features can be used for increasing surface area for heat transfer, increasing capillarity of the wick, modulating porosity with wick height for easier vapor venting etc. This capability is enabled by the lack of a limitation on the number of lithography rounds that can be reliably performed on the oxide, so different pins can be designed to also have multiple levels.

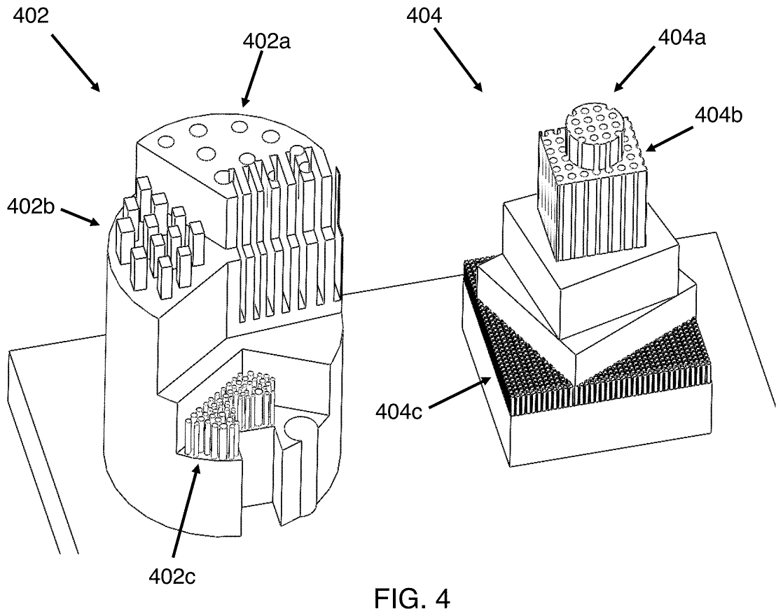

Another capability provided by this technology is well-controlled porosity and/or roughness of individual pin features, as in the examples of FIG. 4. Here pin 402 has holes 402a and controlled roughness 402b, 402c. Similarly, pin 404 has holes 404a, 404b and controlled microroughness 404c. This approach is a reliable way to introduce well controlled multi-height pillared roughness to the base of any microstructure instead of relying on other methods (UV laser rastering, hydrothermal synthesis of nanotube, nanowire etc.) which are stochastic and thus provide less control over the roughness elements and parameters (porosity, element width and height, pitch, density). Base structuring is usually beneficial since it enhances mass transport and typically improves heat transfer performance as well.

FIG. 5 shows an example of a gradient of pin height across the whole array. Here 502 is a monolithic multi-layer wick structure, and the pin array 504 has a height gradient from center to edge. This example is a wick with micro-pillar heights decreasing monotonically as we move towards the center of the device. Such devices, which have wick permeability monotonically increasing as we move to the device periphery can be an attractive solution to the problems associated with the massive liquid-to-vapor volume expansion. During device operation, the expanding vapor often gets trapped in monoporous wicks—unable to escape, they increase vapor pressure within the vapor chamber, which suppresses further phase change (thus reducing thermal performance). The monoporous wick also restricts lateral vapor spreading, which slows vapor transport to the condenser and worsens transport related issues arising in the device. Having taller pins as we move to the device periphery will help reroute the expanding vapor efficiently and quickly away from the hot-spots, thus preventing issues of vapor clogging and accumulation near the hot-spots, thus helping maintain the same high levels of performance at all vapor qualities. A 2.5D version of this gradient idea (where the peripheral pins have a higher pitch instead of taller height, thereby making a pitch gradient) has already been fabricated and demonstrated to work better than a corresponding monoporous counterpart in the literature. The device of FIG. 5 is expected to further improve the performance.

1. A passive wicking-based microfluidic heat spreader comprising:
a monolithically microfabricated array of wicking features, wherein the monolithically microfabricated array of wicking features includes a substrate and features having two or more different vertical feature heights above the substrate;
wherein the monolithically microfabricated array of wicking features does not include any wafer-to-wafer bonds;
wherein the monolithically microfabricated array of wicking features includes features having a vertical feature height of 150 microns or more.

2. The passive wicking-based microfluidic heat spreader of claim 1, wherein the wicking features include one or more pins that rise vertically from the substrate surface.

3. The passive wicking-based microfluidic heat spreader of claim 2, wherein vertical heights of the one or more pins are configured to provide a vertical height gradient in the monolithically microfabricated array of wicking features.

4. The passive wicking-based microfluidic heat spreader of claim 2, wherein one or more of the pins is a multilevel pin having two or more pin features with different vertical heights above the substrate surface.

5. The passive wicking-based microfluidic heat spreader of claim 1, further comprising one or more fluid passages in the substrate.

6. The passive wicking-based microfluidic heat spreader of claim 1, wherein at least one of the fluid passages is configured as a hole passing vertically though the substrate.

7. The passive wicking-based microfluidic heat spreader of claim 1, further comprising one or more vertical vias through the substrate.

8. The passive wicking-based microfluidic heat spreader of claim 7, wherein a height/width aspect ratio of at least one of the vertical vias is 10 or more.

9. A vapor chamber comprising:
a passive wicking-based microfluidic heat spreader according to claim 1;
a capping layer disposed to form an enclosure with the passive wicking-based microfluidic heat spreader;
an evaporative coolant disposed in the enclosure.

10. A vapor chamber comprising:
a first passive wicking-based microfluidic heat spreader according to claim 1; and
a second passive wicking-based microfluidic heat spreader according to claim 1;
wherein the first and second passive wicking-based microfluidic heat spreaders are disposed to form an enclosure; and
an evaporative coolant disposed in the enclosure.
